(19) United States
(12) Patent Application Publication
(10) Pub. No.: US 2011/0037058 A1
(43) Pub. Date: Feb. 17, 2011

(54) OPTOELECTRONIC DEVICE

(75) Inventors: Herwig Buchholz, Frankfurt (DE); Susanne Heun, Bad Soden (DE); Aurélie Ludemann, Frankfurt (DE); Remi Manouk Anemian, Frankfurt (DE)

Correspondence Address: CONNOLLY BOVE LODGE & HUTZ LLP, 1875 EYE STREET, N.W., SUITE 1100, WASHINGTON, DC, 20006, US

(73) Assignee: Merck Patent GmbH Patents & Scientific Information, Darmstadt (DE)

(21) Appl. No.: 12/739,655

(22) PCT Filed: Oct. 24, 2008
(86) PCT No.: PCT/EP2008/009021

§ 371 Date: Oct. 29, 2010

Related U.S. Application Data
(63) Continuation-in-part of application No. 11/923,522, filed on Oct. 24, 2007.

(30) Foreign Application Priority Data
Sep. 3, 2008 (DE) 10 2008 045 664.0

(51) Int. Cl. H01L 51/50; H01L 51/56; C09K 11/06

(52) U.S. Cl. 257/40; 438/46; 252/301.35; 257/E51.018

(57) ABSTRACT

The present invention relates to an opto-electronic device comprising a layer comprising a polymer containing fluorine-containing groups, where an adhesive fluorine-fluorine interaction exists at least between some of the fluorine-containing groups of the layer. The invention is furthermore directed to the use of the opto-electronic device and to a process for the production thereof.

The present invention relates to an opto-electronic device comprising a layer comprising a polymer containing fluorine-containing groups, where a cohesive fluorine-fluorine interaction exists at least between some of the fluorine-containing groups of the layer. The invention is furthermore directed to the use of the opto-electronic device and to a process for the production thereof.

Electronic devices which comprise organic, organometallic and/or polymeric semiconductors are being used ever more frequently in commercial products or are just about to be introduced onto the market. Examples which may be mentioned here are charge-transport materials on an organic basis (for example hole transporters based on triarylamine) in photocopiers and organic or polymeric light-emitting diodes (OLEDs or PLEDs) in display devices or organic photoreceptors in copiers. Organic solar cells (O-SCs), organic field-effect transistors (O-FETs), organic thin-film transistors (O-TFTs), organic integrated circuits (O-ICs), organic optical amplifiers and organic laser diodes (O-lasers) are in an advanced stage of development and may achieve major importance in the future.

Many of these electronic or opto-electronic devices have, irrespective of the respective application, the following general layer structure, which can be adapted for the respective application:
(1) substrate,
(2) electrode, which is frequently metallic or inorganic, but may also be built up from organic or polymeric conductive materials,
(3) optionally one or more charge-injection layers or buffer layers, for example for compensation of the unevenness of the electrode, which is (are) frequently formed from one or more conductive, doped polymer(s),
(4) at least one layer of an organic semiconductor,
(5) optionally one or more further charge-transport or charge-injection or charge-blocking layer(s),
(6) counterelectrode, in which the materials mentioned under (2) are employed,
(7) encapsulation.

The present invention is directed in particular, but not exclusively, to organic light-emitting diodes (OLEDs), which, on use of polymeric materials, are frequently also known as polymeric light-emitting diodes (PLEDs). The above arrangement represents the general structure of an opto-electronic device, where various layers may be combined, meaning that in the simplest case an arrangement consists of two electrodes, between which an organic layer is located. The organic layer in this case fulfils all functions, including the emission of light. A system of this type is described, for example, in WO 90/13148 A1 on the basis of poly(p-phenylenes).

A problem which arises in a “three-layer system” of this type is, however, the lack of control of charge separation or the lack of a possibility of optimising the individual constituents in different layers with respect to their properties, as has been solved in a simple manner, for example, in the case of SMOLEDs (“small-molecule OLEDs”) through a multilayered structure. A “small-molecule OLED” consists, for example, of one or more organic hole-injection layers, hole-transport layers, emission layers, electron-transport layers and electron-injection layers and an anode and a cathode, where the entire system is usually located on a glass substrate. An advantage of a multilayered structure of this type consists in that various functions of charge injection, charge transport and emission can be divided into the different layers and the properties of the respective layers can thus be modified separately.

Typical hole-transport materials in SMOLEDs are, for example, di- and triarylamines, thiophenes, furans or carbazoles, as also investigated and used in photoconductor applications.

Metal chelates, conjugated aromatic hydrocarbons, oxadiazoles, imidazoles, triazines, pyrimidines, pyrazines, pyridazines, phenanthrolines, ketones or phosphine oxides are usually used for the emission and electron-transport layers in SMOLEDs.

The compounds which are used in an SMOLED can frequently be purified by sublimation and are thus available in purities of greater than 99 percent.

The layers in SMOLED devices are usually applied by vapour deposition in a vacuum chamber. However, this process is complex and thus expensive and is unsuitable, in particular, for large molecules, such as, for example, polymers.

Polymeric OLED materials are therefore usually applied by coating from solution. However, the production of a multilayered organic structure by coating from solution requires that the solvent is incompatible with the respective preceding layer in order not to partially dissolve, swell or even destroy the latter again. However, the choice of solvent proves to be difficult, since the organic compounds employed usually have similar properties, in particular similar solution properties. Application of further layers from solution thus becomes virtually impossible or is at least made significantly more difficult.

Correspondingly, polymeric OLEDs in accordance with the prior art are usually built up only from a single-layered or at most two-layered organic structure, where, for example, one of the layers is used for hole injection and hole transport and the second layer is used for the injection and trans-port of electrons and for emission.

In particular in the production of white light-emitting PLEDs, the problem frequently exists that it is difficult or impossible to find a single chromophore which emits light throughout the visible range. Different chromophores are therefore usually copolymerised in the prior art, although colour shifts or quench effects frequently occur here.

One possibility for circumventing this problem of the prior art is the use of blends, for example mixtures of a blue-emitting polymer and a small proportion of a yellow- to red-emitting polymeric or low-molecular-weight compound (for example U.S. Pat. No. 6,127,693). Ternary blends, in which green- and red-emitting polymers or low-molecular-weight compounds are admixed with the blue-emitting polymer, are also known in the literature (for example Y. C. Kim et al., Polymeric Materials Science and Engineering 2002, 87, 286; T.-W. Lee et al., Synth. Metals 2001, 122, 437). A review of such blends is given by S.-A. Chen et al., ACS Symposium Series 1999, 735 (Semiconducting Polymers), 163. These blends have two crucial disadvantages, irrespective of whether they are blends with polymers or low-molecular-weight compounds: the polymers in blends are frequently not ideally miscible with one another and consequently tend towards significantly worse film formation or phase separation in the film. The formation of homogeneous films, as are essential for use in light-emitting diodes, is frequently impossible. Phase separation in the device is also observed on extended operation and results in a reduction in the lifetime and in colour instabilities. Here too, blends are disadvantageous, since the individual blend components age at different rates and thus result in a colour shift. Blends are therefore less suitable than copolymers for use in PLEDs.

White light-emitting PLEDs would be particularly advantageous for the production of full-colour displays and at the same time for simplifying or circumventing complex printing techniques. To this end, a white-emitting polymer could either be applied over a large area or in a structured manner, and the individual colours generated therefrom by a coloured filter, as is already prior art in the case of liquid-crystal displays (LCDs). White-emitting polymers can furthermore be used for monochrome white displays. Furthermore, the use of white-emitting polymers as backlight in liquid-crystal displays is possible, both for monochrome and multicoloured displays. In the broadest possible application, white emission can be employed for general illumination purposes since white is the most similar to sunlight.

It is apparent from the prior art described above that white light-emitting PLEDs would be appropriate, but there is hitherto no solution regarding how high-quality, white-emitting PLEDs can be obtained.

A multilayered structure as in the case of SMOLEDs would apparently also be advantageous in the case of polymeric OLEDs, various approaches having been attempted in the prior art.

Thus, for example, EP 0 637 899 A1 discloses an electroluminescent arrangement comprising one or more organic layers, where one or more of the layers is (are) obtained by thermal or radiation-induced crosslinking. A problem in the case of thermal crosslinking is that the polymeric layers are subjected to a relatively high temperature, which in some cases again results in destruction of the corresponding layer or in the formation of undesired by-products. In the case of crosslinking with actinic radiation, it is frequently necessary to use molecules or moieties which are able to initiate free-radical, cationic or anionic polymerisation. However, it is known in the prior art that molecules or moieties of this type can have adverse effects on the functioning of an opto-electronic device. The use of high-energy actinic radiation is also problematical.

The object of the present invention thus consisted in the provision of an opto-electronic device in which a polymeric layer is fixed without the use of high-energy radiation.

The object is achieved by an opto-electronic device comprising at least one layer comprising a polymer containing fluorine-containing groups, where a cohesive fluorine-fluorine interaction exists at least between some of the fluorine-containing groups of the layer.

This interaction ensures a type of physical crosslinking of the layer in that the fluorinated groups of two or more polymer strands abut against one another and thus result in a “molecular weight increase” (intermolecular dimers, trimers, etc.) without a chemical reaction having to take place. Since the solubility of a layer is dependent on the degree of crosslinking and the effective molecular weight, the cohesive interaction causes insolubility of the layer, even in the solvent from which it was originally deposited. In this way, it is therefore also possible for a plurality of layers to be deposited from a solvent without the layers previously deposited dissolving again.

In a preferred embodiment of the invention, the layer comprises a polymer having a charge-injection and/or charge-transport function.

It is likewise preferred for the layer to comprise a polymer having an emitter function. It is furthermore preferred for the layer to comprise a polymer having a hole-injection and/or hole-transport function and/or emitter function.

In a further embodiment of the invention, it is preferred for the polymer to be a blend of two or more polymers. It is particularly preferred for at least one of the polymers, very particularly preferably all polymers, to contain fluorine-containing groups.

The device according to the invention furthermore comprises at least one further layer.

For the purposes of this invention, it is likewise preferred for the further layer to comprise a polymer having a hole-injection function, hole-transport function, hole-blocking function, emitter function, electron-injection function, electron-blocking function and/or electron-transport function.

The further layer can comprise a further polymer containing fluorine-containing groups. This is always preferred if further layers are to be deposited. Instead of the polymer of the further layer, it is also possible to employ a fluorinated oligomer or a fluorinated small molecule. For the purposes of this invention, an oligomer is taken to mean a molecule which contains more than two, preferably three to nine, recurring units. A polymer preferably contains ten or more recurring units.

In a further preferred embodiment of the invention, it is preferred for the polymer of the further layer to have at least one emitter function. In particular, the polymer having an emitter function should emit light of various wavelengths. This can be achieved by different emitters being present in one or more polymers or a blend in the layer.

In addition, it is preferred for the device to comprise a plurality of layers of polymers having an emitter function. It is particularly preferred here for the plurality of layers of polymers having an emitter function each to emit light of different wavelength.

In a particularly preferred embodiment, it is furthermore preferred for the various wavelengths to add up to the colour white.

A preferred embodiment of the invention comprises, for example, a multilayered arrangement for a white-light emitter, comprising an interlayer and, for example, three layers for the emission of the three primary colours red, green and blue (RGB). These can be deposited in the sequence and layer thickness suitable for the charge and colour balance, where the layers deposited first are rendered insoluble by the cohesive force of the fluorine-fluorine interaction. Singlet and highly efficient triplet emitters can be combined here by distribution over a plurality of layers, which is not possible in one layer.

A further preferred embodiment comprises a blue polymer layer which has been rendered insoluble via F—F interactions and has been overcoated with a layer comprising a yellow triplet emitter. The yellow triplet emitter can be a true yellow emitter or an emitter which is composed of a red emitter and a green emitter. The use of stable triplet emitters of high efficiency enables a white light-emitting system of high efficiency and long lifetime to be obtained. This system is, in addition, distinguished by a simple production method (vacuum vapour deposition unnecessary) and thus lower costs.

In still a further embodiment of the invention, the device may comprise a plurality of layers of polymers having a hole-conductor function, where the hole conductors have energetically different highest occupied molecular orbitals (HOMO).

It is particularly preferred here for the polymer layer having a hole-conductor function which was applied last to have an energetically high lowest unoccupied molecular orbital (LUMO). In this way, the polymer layer which was applied last is an electron-blocking layer.

In still a further embodiment of the invention, the device may comprise a plurality of layers of polymers having an electron-conductor function, where the electron conductors have energetically different lowest unoccupied molecular orbitals (LUMO).

It is particularly preferred here for the polymer layer having an electron-conductor function which was applied first to have an energetically low highest occupied molecular orbital (HOMO). In this way, the polymer layer which was applied first is a hole-blocking layer.

A preferred embodiment thus comprises a multilayered arrangement comprising a plurality of (partially) fluorinated polymeric hole conductors and/or electron conductors (interlayer) with different HOMO (“highest occupied molecular orbital”) and a corresponding electron- or hole-blocking function. Improved hole or electron injection can thus be achieved owing to graduated barrier steps.

It may furthermore be advantageous in accordance with the invention for the device to comprise a layer (or a plurality of layers) comprising small molecules or oligomers. This is preferably applied as the final layer (before a cathode). The layer can be applied by coating from solution, by printing processes, by vapour deposition or by other methods known from the prior art.

“Some” of the fluorine-containing groups means that about 1 to 100%, preferably 40 to 100% and particularly preferably 80% to 100%, of the fluorine-containing groups undergo an interaction. The fluorine-containing groups here should interact with one another within the layer in the highest possible proportion in order to enhance the crosslinking character of the layer. In order to undergo an interaction with one another, the separation of the fluorine atoms should correspond approximately to the van der Waals radius. The separation of the fluorine atoms to one another is at least such that an attractive F—F interaction occurs, comparable with the interaction in the case of hydrogen bonds. A polymer in a layer according to the invention preferably comprises 0.5 to 100%, particularly preferably 1 to 50% and in particular 1 to 25%, of fluorine-containing groups, based on the recurring units of the polymer. 100% thus means that every recurring unit of the polymer contains fluorine-containing groups.

The device according to the invention furthermore comprises an electrode (anode), where the electrode (anode) is preferably an indium tin oxide (ITO) layer or an indium zinc oxide (IZO) layer or a conductive polymer, or a combination of the two. The conductive polymer is preferably selected from PEDOT or PANI. Further preferred (intrinsically) conductive polymers are polythiophene (PTh), poly(3,4-ethylenedioxythiophene) (PEDT), poly-diacetylene, polyacetylene (PAc), polypyrrole (PPy), polyisothianaphthene (PITN), polyheteroarylenevinylene (PArV), where the heteroarylene group can be, for example, thiophene, furan or pyrrole, poly-p-phenylene (PpP), polyphenylene sulfide (PPS), polyperinaphthalene (PPN), polyphthalo-cyanine (PPc) inter alia, and derivatives thereof (which are formed, for example, from monomers substituted by side chains or groups), copolymers thereof and physical mixtures thereof.

In addition, the opto-electronic device according to the invention preferably comprises a cathode and advantageously also an encapsulation.

The opto-electronic device according to the invention can be used as organic or polymeric light-emitting diode, as organic solar cell, as organic field-effect transistor, as organic integrated circuit, as organic field-quench element, as organic optical amplifier, as organic laser diode, as organic photoreceptor and as organic photodiode.

The opto-electronic device according to the invention can be used as OLED in a display, in a coloured, multicoloured or full-colour display, as lighting element or as backlight in a liquid-crystal display (LCD). The opto-electronic device can preferably be used as white light-emitting OLED.

The opto-electronic device according to the invention can be used in a white-emitting display.

The opto-electronic device according to the invention can be used in a coloured, multicoloured or full-colour display, where the colour is generated through the use of a coloured filter on a white-emitting PLED.

The opto-electronic device according to the invention can be used as lighting element.

The opto-electronic device according to the invention can be used in a liquid-crystal display (LCD) containing a white-emitting PLED as backlight.

For the purposes of this invention, the fluorine-containing groups R_{f} preferably have the general formula CₓH_{y}F_{z}, where x≧0, y≧0 and z≧1, and no, one or more CH₂ groups, which may also be adjacent, may be replaced by O, S, Se, Te, Si(R¹)₂, Ge(R¹)₂, NR¹, PR¹, CO, P(R¹)O, where R¹ is on each occurrence, identically or differently, a straight-chain, branched or cyclic alkyl, alkenyl, alkynyl, aryl, arylalkyl, arylalkenyl, aryl-alkynyl, heteroaryl or heteroalkyl group, where, in addition, one or more non-adjacent C atoms of the non-aromatic moieties may be replaced by O, S, CO, COO or OCO, with the proviso that two radicals R¹ may also form ring systems with one another. Preferred groups include, for example, F, CF₃, C₂F₅, CF₃(CH₂)ₐS, CF₃CF₂S and (CF₃—(CH₂)ₐ)₂N, where a preferably represents an integer from 0 to 5.

Surprisingly, it has been found that, after application of a fluorinated polymer or a polymer containing fluorinated or perfluorinated side groups from solution, the polymer can no longer be dissolved or washed off and also does not swell after removal of the solvent. It was thus possible to fix the layer without the use of high temperatures and without the use of high-energy radiation. It is thus possible to apply a further layer from solution without problems without damaging the structure of the preceding layer. Surprisingly, it has, in addition, been found that, on application of a plurality of fluorinated polymers (or fluorinated oligomers or fluorinated small molecules), adhesion to one another is caused by the fluorine-fluorine interaction of the layers. The individual layers are not partially dissolved again and also do not swell due to the application of further layers from solution. In this way, polymeric, multilayered devices can be provided, as are known from “small-molecule OLEDs”.

The first layer is preferably located on a substrate, on which an electrode is usually located. Preferred materials for the substrate are, for example, glasses and films which have adequate mechanical stability and guarantee a barrier action. The substrate may, for example, have an electrically conductive coating, or an indium tin oxide (ITO) or indium zinc oxide (IZO) can be applied, which is usually carried out by sputtering.

It is likewise possible for a conductive polymer to be applied to the substrate, for example by coating from solution, and to serve as electrode. The conductive polymer is preferably selected from PEDOT and PANI. It may be modified by fluorinated groups. The polymer is preferably doped and can thus function as charge-injection layer. The polymer is preferably a polythiophene derivative, particularly preferably poly(3,4-ethylenedioxy-2,5-thiophene) (PEDOT) or polyaniline (PANI). The polymers are preferably doped with polystyrenesulfonic acid or another polymer-bound Brönsted acids and thus converted into a conductive state.

It is furthermore preferred for the first layer to include a hole-injection injection and/or a hole-transport function. Both functions can be provided, for example, by doped polythiophene derivatives or polyanilines.

For the purposes of this invention, the first layer may likewise preferably include an emitter function. This can be carried out, for example, by co-polymerisation of emitter compounds or photoluminescent compounds with the monomers of the corresponding polymer. The emitter compounds or photoluminescent or electroluminescent compounds may be located in the main chain or side chain of the polymer or may, for example, be grafted to suitable sites. It is likewise possible to employ monomeric or polymeric emitter compounds, which may likewise contain fluorine-containing groups.

The opto-electronic device according to the invention preferably comprises a second layer. It is likewise preferred for further additional layers to be present in the device besides the second layer. For the purposes of this invention, it is preferred for the additional layer (or the additional layers) to comprise compounds containing fluorine-containing groups, preferably as defined above. The additional layer may thus also comprise a partially fluorinated polymer or a polymer containing fluorinated or perfluorinated side groups, but also an oligomer containing fluorinated groups or a fluorinated molecule (small molecule).

In accordance with the invention, the opto-electronic device is distinguished by the fact that some of the fluorine-containing groups of the additional layer and of the respective preceding layer are located at a separation from one another such that an adhesive fluorine-fluorine interaction exists. For the purposes of this invention, the additional layer can be a charge-injection layer (hole- or electron-injection layer), a charge-transport layer (hole- or electron-transport layer), an emitter layer, a hole- or electron-blocking layer and/or a combination thereof. This in turn means that the additional layer may combine a plurality of functions in one layer, or that a plurality of additional layers take on the corresponding functions.

A classical structure comprising substrate, electrode, multifunction layer and cathode or a structure as in the case of a small-molecule OLED, namely a structure comprising
1) substrate,
2) electrode or anode,
3) hole-injection layer(s),
4) hole-transport layer(s),
5) emission layer(s),
6) electron-transport layer(s),
7) electron-injection layer(s) and
8) counterelectrode or cathode,
   is thus possible in accordance with the invention.

In accordance with the invention, one or more of the layers may be combined with one another, or the structure comprising polymeric layers may be combined with layers as are known from an SMOLED. For example, components can be applied by vapour deposition or printing, if desired, or components can be applied from solution, where the components preferably contain fluorine-containing groups.

In this way, devices having relatively thick layers can be provided, where these layers can function, for example, as hole-injection layers or electron-barrier layers. Layers of this type can be optimised in a simple manner with respect to their colour and effectiveness. In addition, the lifetime of a layer of this type is increased by an improved electron-barrier function (fewer tunnel effects in the underlying layer, particularly the case for PEDOT).

For the purposes of the present invention, the opto-electronic device is suitable as organic or polymeric light-emitting diode, as organic solar cell (O-SC, for example WO 98/48433, WO 94/05045), as organic field-effect transistor (O-FET), as organic integrated circuit (O-IC, for example WO 95/31833, WO 99/10939), as organic field-quench element (FDQ, for example US 2004/017148), as organic optical amplifier, as organic photo-receptor, as organic photodiode or as organic laser diode (O-LASER, for example WO 98/03566), and can be used correspondingly thereto.

For use in O-FETs, materials having high charge-carrier mobility are of particular interest. These are, for example, oligo- or poly(triarylamines), oligo- or poly(thiophenes) and copolymers which contain a high proportion of these units.

The device is structured correspondingly (depending on the application), provided with contacts and finally hermetically sealed, since the lifetime of devices of this type is drastically shortened in the presence of water and/or air. It may also be preferred here to use a conductive, doped polymer as electrode material for one or both of the electrodes and not to introduce an interlayer comprising conductive, doped polymer.

For applications in O-FETs and O-TFTs, it is additionally necessary for the structure to comprise, apart from electrode and counterelectrode (source and drain), a further electrode (gate), which is isolated from the organic semiconductor by an insulator layer having a generally high (or rarely low) dielectric constant. In addition, it may be appropriate to introduce further layers into the device.

For the purposes of this invention, the electrodes are selected in such a way that their potential corresponds as well as possible to the potential of the adjacent organic layer in order to ensure the most efficient electron or hole injection possible.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, can also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides (for example LiF, Li₂O, BaF₂, MgO, NaF, etc.). The layer thickness of this layer is preferably between 1 and 10 nm.

The anode preferably comprises materials having a high work function. The anode preferably has a potential of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be trans-parent in order either to enable irradiation of the organic material (O-SCs) or the coupling-out of light (OLEDs/PLEDs, O-lasers). A preferred structure uses a transparent anode. Preferred anode materials here are conductive mixed metal oxides. Particular preference is given to indium tin oxide (ITO) or indium zinc oxide (IZO) containing fluorine-containing groups. Preference is furthermore given to conductive, doped organic materials, in particular conductive doped polymers, which preferably contain fluorine-containing groups, as defined above.

Suitable as hole-injection layer on the anode are various doped, conductive polymers. Preference is given to polymers which have a conductivity >10⁻⁸ S/cm, depending on the application. The potential of the layer is preferably 4 to 6 eV vs. vacuum. The layer thickness is preferably between 10 and 500 nm, particularly preferably between 20 and 250 nm. Particular preference is given to the use of derivatives of polythiophene (in particular poly(3,4-ethylenedioxy-2,5-thiophene) (PEDOT) and polyaniline (PANI)). Further preferred (intrinsically) conductive polymers are polythiophene (PTh), poly(3,4-ethylenedioxythiophene) (PEDOT), polydiacetylene, polyacetylene (PAc), polypyrrole (PPy), polyisothianaphthene (PITN), poly-heteroarylenevinylene (PArV), where the heteroarylene group can be, for example, thiophene, furan or pyrrole, poly-p-phenylene (PpP), polyphenyl-ene sulfide (PPS), polyperinaphthalene (PPN), polyphthalocyanine (PPc) inter alia, and derivatives thereof (which are formed, for example, from monomers substituted by side chains or groups), copolymers thereof and physical mixtures thereof. The doping is generally carried out by means of acids or by means of oxidants. The doping is preferably carried out by means of polymer-bound Brönsted acids. Particular preference is given for this purpose to polymer-bound sulfonic acids, in particular poly(styrene-sulfonic acid) and poly(vinylsulfonic acid). The conductive polymer for the charge-injection layer preferably contains fluorine-containing groups, causing fixing of the layer through cohesive F—F interactions to take place after application from solution and removal of the solvent.

Besides emitting recurring units, the polymer of the emitter layer preferably contains further recurring units, which likewise preferably contain fluorine-containing groups or substituents. This may be a single polymeric compound or a blend of two or more polymeric compounds or a blend of one or more polymeric compounds with one or more low-molecular-weight organic compounds. The organic emitter layer can preferably be applied by coating from solution or by various printing processes, in particular by ink-jet printing processes. The polymeric compound and/or the further compounds preferably contain fluorine-containing groups. The layer thickness of the organic semiconductor is preferably 10 to 500 nm, particularly preferably 20 to 250 nm, depending on the application.

Preferred recurring units in the polymer of the emitter layer are, for example, the compounds shown below, without being restricted thereto:

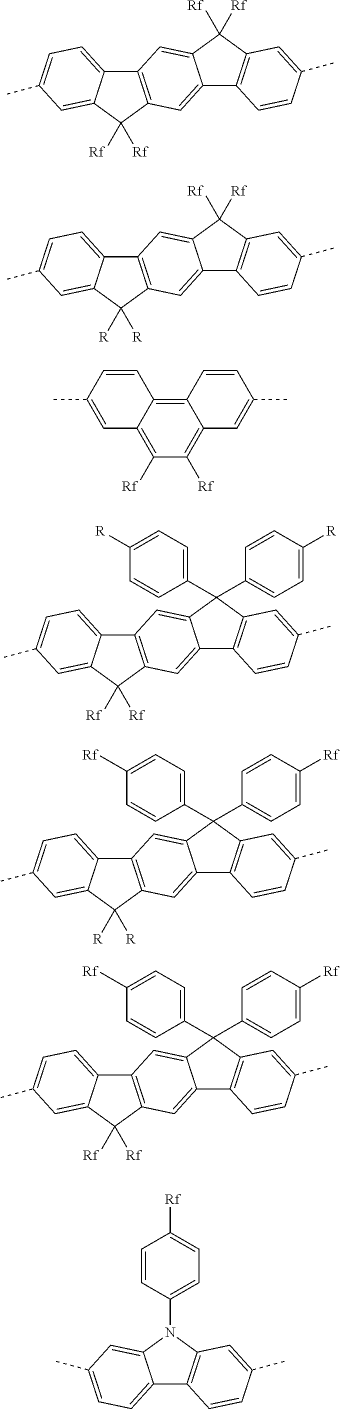

In these formulae, Rf denotes a fluorinated radical of the general formula CₓH_{y}F_{z}, where x≧0, y≧0 and z≧1, and no, one or more CH₂ groups, which may also be adjacent, may be replaced by O, S, Se, Te, Si(R¹)₂, Ge(R¹)₂, NR¹, PR¹, CO, P(R¹)O, where R¹ and R are on each occurrence, identically or differently, a straight-chain, branched or cyclic alkyl, alkenyl, alkynyl, aryl, arylalkyl, arylalkenyl, arylalkynyl, heteroaryl or heteroalkyl group, where, in addition, one or more non-adjacent C atoms of the non-aromatic moieties may be replaced by O, S, CO, COO or OCO, with the proviso that two radicals R¹ may also form ring systems with one another. Preferred groups include, for example, F, CF₃, C₂F₅, CF₃(CH₂)ₐS, CF₃CF₂S and (CF₃—(CH₂)ₐ)₂N, where a preferably represents an integer from 0 to 5. Preferred polymers or fluorine-containing polymers (or polymers containing fluorinated or perfluorinated side groups) for the purposes of this invention are conjugated polymers or partially conjugated polymers which contain sp²-hybridised carbon atoms in the main chain, which may also be replaced by corresponding heteroatoms. Furthermore, the term conjugated is likewise used for the purposes of this invention if, for example, arylamine units and/or certain heterocycles (i.e. conjugation via N, O or S atoms) and/or organometallic complexes (i.e. conjugation via the metal atom) are located in the main chain. Typical representatives of conjugated polymers as can be used, for example, in PLEDs or O-SCs are poly-para-phenylenevinylenes (PPVs), polyfluorenes, polyspirobifluorenes, polyphenanthrenes, polydihydrophenanthrenes, polyindenofluorenes, systems based in the broadest sense on poly-p-phenylenes (PPPs), and derivatives of these structures, in particular derivatives which contain fluorine-containing groups.

Particular preference is given in accordance with the invention to polymers which contain further structural elements and should thus be referred to as copolymers. Reference should also be made here, in particular, to the relatively extensive lists of possible structural elements in WO 02/077060, WO 2005/014689 and the references cited in these specifications. These further structural units can originate, for example, from the classes described below:
Group 1: structural units which represent the polymer backbone.
Group 2: structural units which enhance the hole-injection and/or -transport properties of the polymers.
Group 3: structural units which enhance the electron-injection and/or -transport properties of the polymers.
Group 4: structural units which have combinations of individual units from group 2 and group 3.
Group 5: structural units which influence the morphology and/or emission colour of the resultant polymers.
Group 6: structural units which modify the emission characteristics to such an extent that electrophosphorescence can be obtained instead of electrofluorescence.
Group 7: structural units which improve the transfer from the singlet state to the triplet state.

Suitable and preferred units for the above-mentioned groups are described below, where these preferably contain the fluorine-containing groups defined in accordance with the invention.

Group 1—Structural Units which Represent the Polymer Backbone:

Preferred units from group 1 are, in particular, those which contain aromatic or carbocyclic structures having 6 to 40 C atoms. Suitable and preferred units are, inter alia, fluorene derivatives, as disclosed, for example, in EP 0842208, WO 99/54385, WO 00/22027, WO 00/22026 and WO 00/46321, indenofluorenes, furthermore spirobifluorene derivatives, as disclosed, for example, in EP 0707020, EP 0894107 and WO 03/020790, phenanthrene derivatives or dihydrophenanthrene derivatives, as disclosed, for example, in WO 2005/014689. It is also possible to use a combination of two or more of these monomer units, as described, for example, in WO 02/077060. Preferred units for the polymer backbone are, in particular, spirobifluorene, indenofluorene, phenanthrene and dihydrophenanthrene derivatives.

Particularly preferred units from group 1 are divalent units of the following formulae, in which the dashed lines denote the links to the adjacent units:

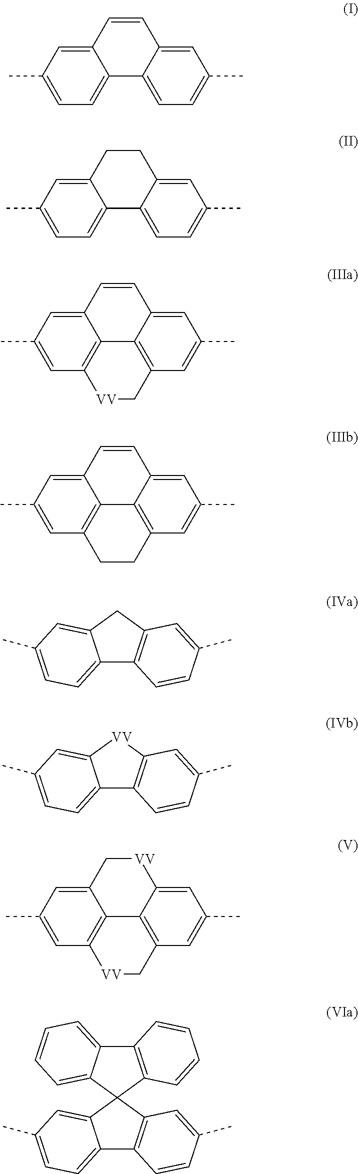

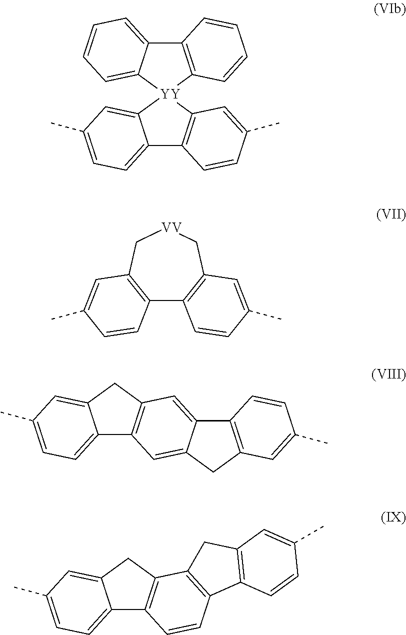

in which the individual radicals have the following meanings:

### YY is Si or Ge,

### VV is O, S or Se,

and where the various formulae may also additionally be substituted in the free positions by one or more substituents R², and R² has the following meaning:
R² is on each occurrence, identically or differently, H, a straight-chain, branched or cyclic alkyl or alkoxy chain having 1 to 22 C atoms, in which, in addition, one or more non-adjacent C atoms may be replaced by O, S, CO, O—CO, CO—O or O—CO—O, where, in addition, one or more H atoms may be replaced by fluorine, an aryl or aryloxy group having 5 to 40 C atoms, in which, in addition, one or more C atoms may be replaced by O, S or N and which may also be substituted by one or more non-aromatic radicals R², or F, CN, N(R³)₂ or B(R³)₂; and
R³ is on each occurrence, identically or differently, H, a straight-chain, branched or cyclic alkyl chain having 1 to 22 C atoms, in which, in addition, one or more non-adjacent C atoms may be replaced by O, S, CO, O—CO, CO—O or O—CO—O, where, in addition, one or more H atoms may be replaced by fluorine, or an optionally substituted aryl group having 5 to 40 C atoms, in which, in addition, one or more C atoms may be replaced by O, S or N.
Group 2—Structural Units which Enhance the Hole-Injection and/or -Transport Properties of the Polymers:

These are generally aromatic amines or electron-rich heterocycles, such as, for example, substituted or unsubstituted triarylamines, benzidines, tetraarylene-para-phenylenediamines, phenothiazines, phenoxazines, dihydrophenazines, thianthrenes, dibenzo-p-dioxins, phenoxathiynes, carbazoles, azulenes, thiophenes, pyrroles, furans and further O-, S- or N-containing heterocycles having a high HOMO (HOMO=highest occupied molecular orbital). However, triarylphosphines, as described, for example, in WO 2005/017065 A1, are also suitable here.

Particularly preferred units from group 2 are divalent units of the following formulae, in which the dashed lines denote the links to the adjacent units:

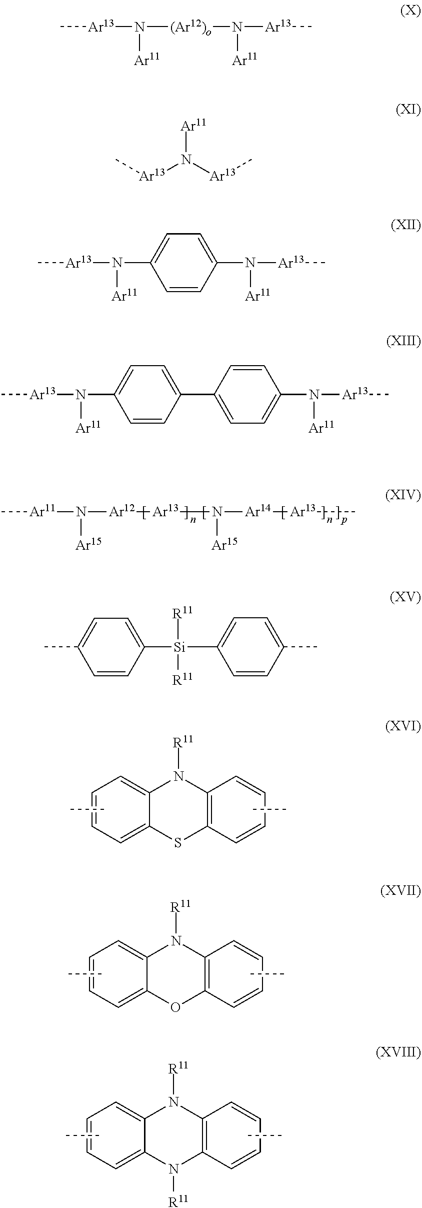

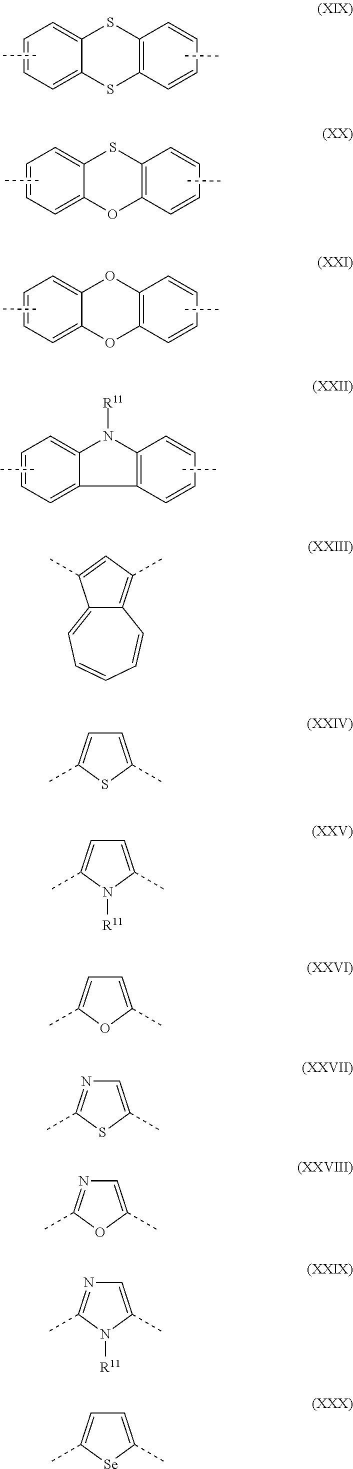

where R¹¹ has one of the meanings indicated above for R², the various formulae may also additionally be substituted in the free positions by one or more substituents R¹¹, and the symbols and indices have the following meanings:
n is, identically or differently on each occurrence, 0, 1 or 2,
p is, identically or differently on each occurrence, 0, 1 or 2, preferably 0 or 1,
o is, identically or differently on each occurrence, 1, 2 or 3, preferably 1 or 2,
Ar¹¹, Ar¹³ are on each occurrence, identically or differently, an aromatic or heteroaromatic ring system having 2 to 40 C atoms, which may be mono- or polysubstituted by R¹¹ or also unsubstituted; the possible substituents R¹¹ here can potentially be in any free position,
Ar¹², Ar¹⁴ are on each occurrence, identically or differently, Ar¹¹, Ar¹³ or a substituted or unsubstituted stilbenzylene or tolanylene unit,
Ar¹⁵ is, identically or differently on each occurrence, either a system as described by Ar¹¹ or an aromatic or heteroaromatic ring system having 9 to 40 aromatic atoms (C or heteroatoms), which may be mono- or polysubstituted by R¹¹ or unsubstituted and which consists of at least two condensed rings; the possible substituents R¹¹ here can potentially be in any free position.

Group 3—Structural Units which Enhance the Electron-Injection and/or -Transport Properties of the Polymers:

These are generally electron-deficient aromatics or heterocycles, such as, for example, substituted or unsubstituted pyridines, pyrimidines, pyridazines, pyrazines, pyrenes, perylenes, anthracenes, benzanthracenes, oxadiazoles, quinolines, quinoxalines, phenazines, benzimidazoles, ketones, phosphine oxides, sulfoxides or triazines, but also compounds such as triarylboranes and further O-, S- or N-containing heterocycles having a low LUMO (LUMO=lowest unoccupied molecular orbital), and benzophenones and derivatives thereof, as disclosed, for example, in WO 05/040302.

Particularly preferred units from group 3 are divalent units of the following formulae, in which the dashed lines denote the links to the adjacent units:

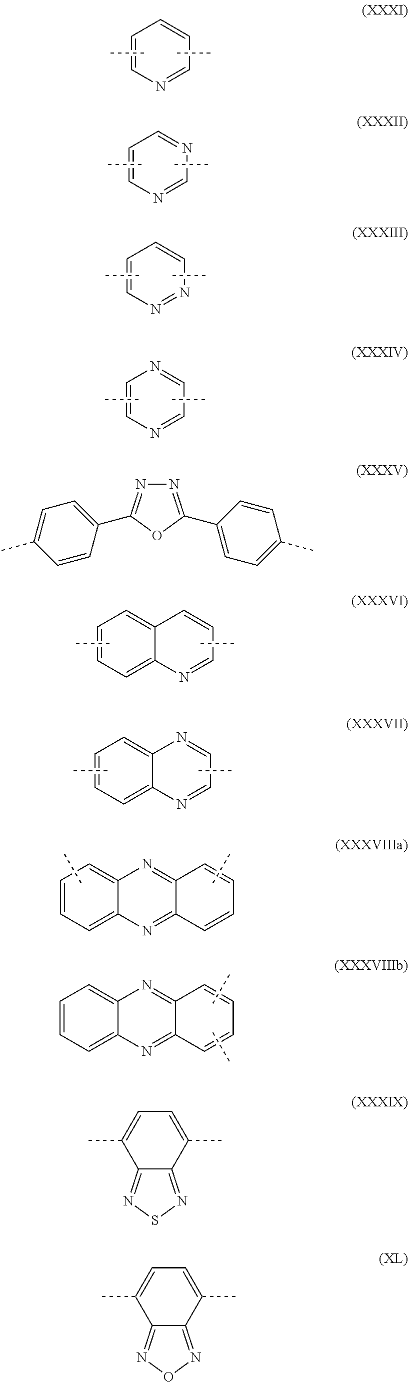

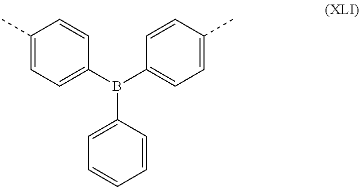

where the various formulae may be substituted in the free positions by one or more substituents R¹¹ as defined above.
Group 4—Structural Units which have Combinations of Individual Units from Group 2 and Group 3:

It is also possible for the polymers to contain units in which structures which increase the hole mobility and the electron mobility or both are bonded directly to one another. However, some of these units shift the emission colour into the yellow or red. Their use in the opto-electronic device according to the invention for generating blue or green emission is therefore less preferred.

If such units from group 4 are present in the polymers, they are preferably selected from divalent units of the following formulae, in which the dashed lines denote the links to the adjacent units:

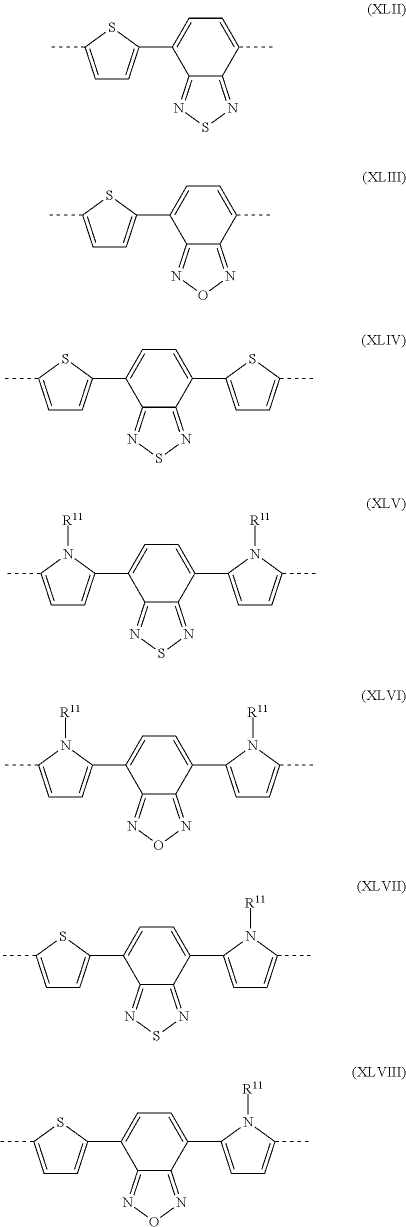

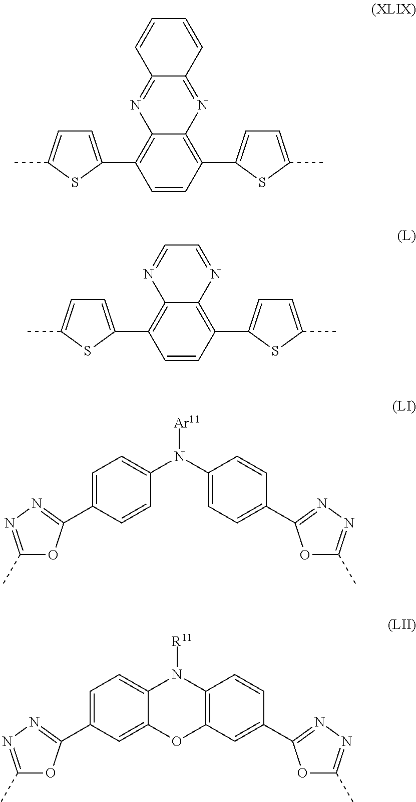

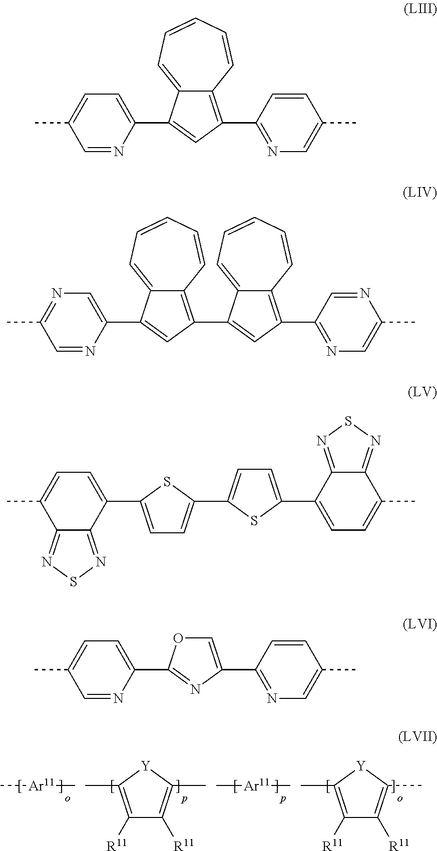

where the various formulae may be substituted in the free positions by one or more substituents R¹¹, the symbols R¹¹, Ar¹¹, p and o have the meanings indicated above, and Y is on each occurrence, identically or differently, O, S, Se, N, P, Si or Ge.
Group 5—Structural Units which Influence the Morphology and/or Emission Colour of the Resultant Polymers:

Besides the units mentioned above, these are those which have at least one further aromatic or another conjugated structure which does not fall under the above-mentioned groups, i.e. which has only little effect on the charge-carrier mobility, which are not organometallic complexes or which have no influence on the singlet-triplet transfer. Structural elements of this type may influence the morphology, but also the emission colour of the resultant polymers. Depending on the unit, they can therefore also be employed as emitters. Preference is given here to substituted or unsubstituted aromatic structures having 6 to 40 C atoms or also tolane, stilbene or bisstyrylarylene derivatives, each of which may be substituted by one or more radicals R¹¹. Particular preference is given here to the incorporation of 1,4-phenylene, 1,4-naphthylene, 1,4- or 9,10-anthrylene, 1,6-, 2,7- or 4,9-pyrenylene, 3,9- or 3,10-perylenylene, 4,4′-biphenylylene, 4,4″-terphenylylene, 4,4′-bi-1,1′-naphthylylene, 4,4′-tolanylene, 4,4′-stilbenzylene or 4,4″-bisstyrylarylene derivatives.

Very particular preference is given to substituted or unsubstituted structures of the following formulae, in which the dashed lines denote the links to the adjacent units:

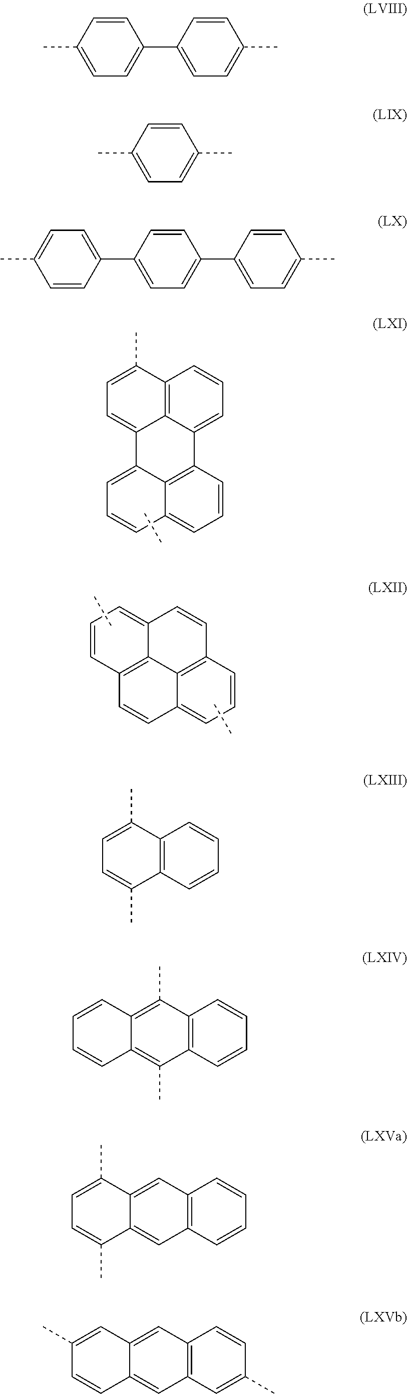

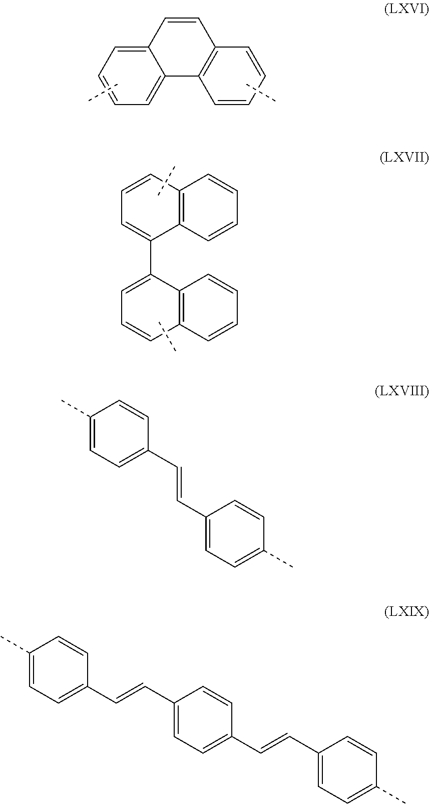

where the various formulae may be substituted in the free positions by one or more substituents R¹¹ as defined above.
Group 6—Structural Units which Modify the Emission Characteristics to Such an Extent that Electrophosphorescence can be Obtained Instead of Electrofluorescence:

These are, in particular, those units which are able to emit light from the triplet state with high efficiency even at room temperature, i.e. exhibit electrophosphorescence instead of electrofluorescence, which frequently causes an increase in the energy efficiency. Suitable for this purpose are firstly compounds which contain heavy atoms having an atomic number of greater than 36. Particularly suitable compounds are those which contain d- or f-transition metals which satisfy the above-mentioned condition. Very particular preference is given here to corresponding structural units which contain elements from groups 8 to 10 (Ru, Os, Rh, Ir, Pd, Pt). Suitable structural units for the polymers here are, for example, various complexes which are described, for example, in WO 02/068435, WO 02/081488, EP 1239526 and WO 04/026886. Corresponding monomers are described in WO 02/068435 and WO 2005/042548 A1.

Preferred units from group 6 are those of the following formulae, in which the dashed lines denote the links to the adjacent units:

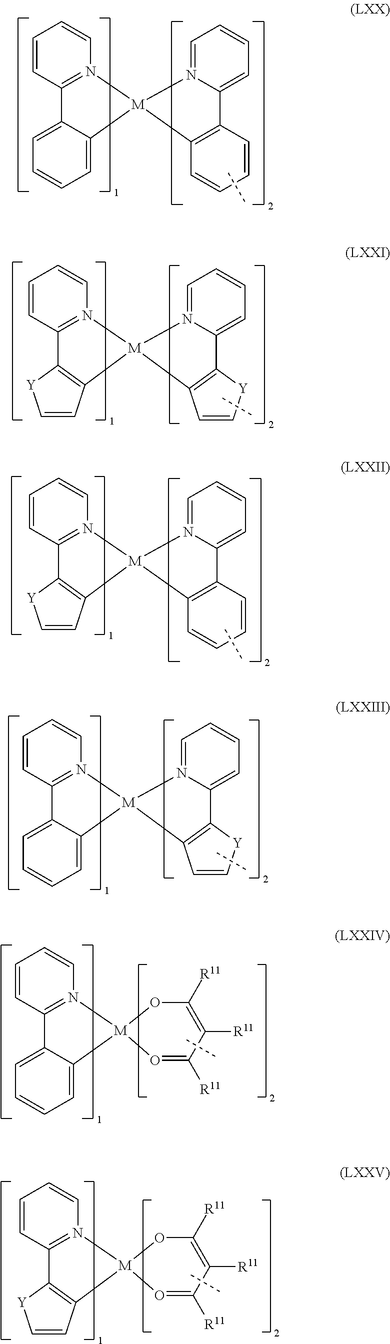

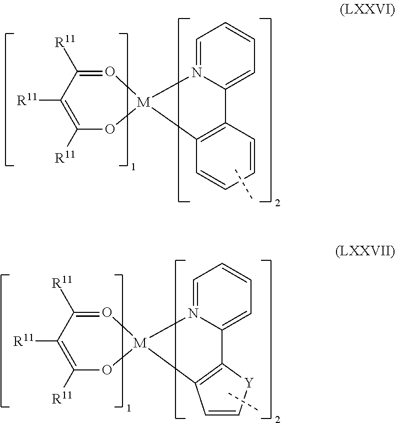

in which M stands for Rh or Ir, Y has the above-mentioned meaning, and the various formulae may be substituted in the free positions by one or more substituents R¹¹ as defined above.
Group 7—Structural Units which Improve the Transfer from the Singlet State to the Triplet State:

These are, in particular, those units which improve the transfer from the singlet state to the triplet state and which, employed in support of the structural elements from group 6, improve the phosphorescence properties of these structural elements. Suitable for this purpose are, in particular, carbazole and bridged carbazole dimer units, as described, for example, in WO 04/070772 and WO 04/113468. Also suitable for this purpose are ketones, phosphine oxides, sulfoxides and similar compounds, as described, for example, in WO 2005/040302 A1.

It is also possible for more than one structural unit from one of groups 1 to 7 to be present simultaneously.

The polymer may furthermore likewise contain metal complexes, which are generally built up from one or more ligands and one or more metal centres, bonded into the main or side chain.

Preference is given to polymers which additionally also contain one or more units selected from groups 1 to 7.

It is likewise preferred for the polymers to contain units which improve the charge transport or charge injection, i.e. units from group 2 and/or 3; a proportion of 1 to 30 mol % of these units is particularly preferred; a proportion of 2 to 10 mol % of these units is very particularly preferred.

It is furthermore particularly preferred for the polymers to contain units from group 1, units from group 2 and/or 3, and units from group 5.

The polymers preferably contain 10 to 10,000, particularly preferably 20 to 5000 and in particular 50 to 2000, recurring units. A distinction should be made between these and the fluorinated oligomers according to the invention, which contain 3 to 9 recurring units. Otherwise, the oligomers may also contain all recurring units defined above, including the emitters.

The requisite solubility of the polymers is ensured, in particular, by the substituents on the various recurring units.

The polymers may be linear, branched or crosslinked. The copolymers according to the invention may have random, alternating or block-like structures or also have a plurality of these structures in an alternating arrangement. The way in which copolymers having block-like structures can be obtained and which further structural elements are particularly preferred for this purpose are described in detail, for example, in WO 2005/014688. This specification is incorporated into the present application by way of reference.

The polymers are generally prepared by polymerisation of one or more types of monomer. Suitable polymerisation reactions are known to the person skilled in the art and are described in the literature. Particularly suitable and preferred polymerisation and coupling reactions, all of which result in C—C links, are the SUZUKI, YAMAMOTO, STILLE, HECK, NEGISHI, SONOGASHIRA or HIYAMA reactions.

The way in which the polymerisation can be carried out by these methods and the way in which the polymers can then be separated off from the reaction medium and purified are known to the person skilled in the art and are described in detail in the literature, for example in WO 2003/048225 and WO 2004/037887.

The C—C linking reactions are preferably selected from the groups of the SUZUKI coupling, the YAMAMOTO coupling and the STILLE coupling.

For the synthesis of the polymers, the corresponding monomers are required. The synthesis of units from groups 1 to 7 is known to the person skilled in the art and is described in the literature, for example in WO 2005/014689. This and the literature cited therein are incorporated into the present application by way of reference.

In order to achieve the partial fluorination of the polymers, the monomers can be modified with the groups of the general formula CₓH_{y}F_{z}, mentioned above and copolymerised as constituents of the copolymers.

It may additionally be preferred to use the polymer not as the pure substance, but instead as a mixture (blend) together with further polymeric, oligomeric, dendritic or low-molecular-weight substances of any desired type. These may, for example, improve the electronic properties or emit themselves. The present invention therefore also relates to blends of this type.

The invention furthermore relates to solutions and formulations comprising one or more fluorine-containing polymers and/or fluorine-containing blends and/or fluorinated small molecules in accordance with the invention (as defined above) in one or more solvents. The way in which polymer solutions or solutions of small molecules can be prepared is known to the person skilled in the art and is described, for example, in WO 02/072714, WO 03/019694 and the literature cited therein. The solutions and formulations may optionally comprise one or more additives.

These solutions can be used in order to produce thin polymer layers, for example by area-coating methods (for example spin coating) or by printing processes (for example ink-jet printing), in particular in the process according to the invention.

The invention also relates to a process for the production of an opto-electronic device, comprising the production of a layer of a polymer containing fluorine-containing groups.

The process preferably comprises the steps of
a) application of a first layer to a substrate, and
b) application of at least one second layer.

The first layer is preferably a partially fluorinated hole-injection layer consisting of a partially fluorinated copolymer which has been prepared before the deposition by copolymerisation with fluorinated monomers or polymer-analogous fluorination.

In a preferred embodiment, the electrode used is indium tin oxide (ITO) or indium zinc oxide (IZO). This can be modified with the aid of CF₄ plasma treatment in order additionally to generate an adhesive interaction with the following fluorinated layer.

The first layer is likewise preferably the emitter layer itself, which is functionalised in advance through the use of fluorinated monomers and is applied to the PANI or PEDOT layer or a hole-injecting interlayer. In addition, electron-transporting or hole-blocking layers can then be applied from other or even the same solvent.

The substrate used in accordance with the invention is glass or a polymer film, preferably glass.

In a further preferred embodiment, the electrode is a conductive polymer, and the fluorine-containing groups are introduced into the conductive polymer before application of the electrode to the substrate. The conductive polymer used is preferably one of the conjugated polymers PEDOT or PANI defined above, which are preferably provided with fluorine-containing groups. In the case of a conductive polymer, the fluorination is carried out by methods in accordance with the prior art, for example by polymerising fluorinated monomers or by fluorinating the finished polymer.

The component containing fluorine-containing groups is preferably a partially fluorinated polymer or a polymer containing fluorinated or perfluorinated side groups, an oligomer containing fluorinated groups, a fluorinated molecule, or combinations thereof.

The second layer is preferably applied by coating from a solution containing the polymer, for example by spin coating or knife coating. For the second layer, a partially fluorinated polymer, a polymer containing perfluorinated side groups, an oligomer containing fluorinated groups or a fluorinated molecule is used. It is furthermore preferred for the second layer to have a charge-injection function, an emitter function, a barrier function or combinations of the said functions. To this end, it is possible, for example, to employ a conjugated polymer defined above which has the corresponding functions or to employ corresponding oligomers or molecules. The emitters defined above can likewise be employed in the process according to the invention.

One or more additional layers can then be applied to the applied layer without partially dissolving or swelling the fixed layer. The fluorine-containing groups of this layer prevent, via the strong intermolecular interactions, the detachment of the applied material, which is equivalent to the action of a crosslinking reaction.

In addition, thicker layers can be produced in this way which function, for example, as hole-injection layers or electron-barrier layers, and these layers can be optimised with respect to colour and effectiveness. In addition, the lifetime of a layer of this type can be increased by an improved electron-barrier function (fewer tunnel effects in the underlying layer, in particular the case for PEDOT).

When all the additional layers have been applied successively, a cathode is furthermore applied by methods known from the prior art. Finally, an encapsulation is applied in order to protect the device against external influences, such as water vapour, oxygen and the like.

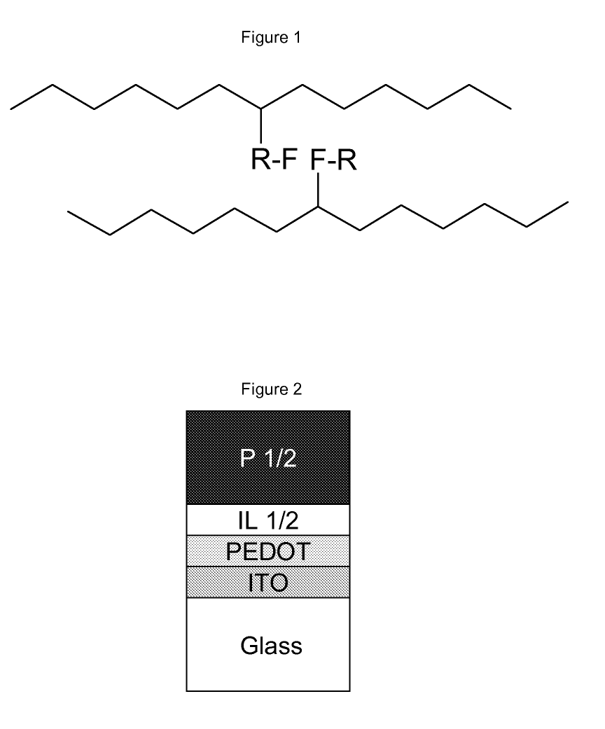

The invention will now be explained in greater detail with reference to an illustrative embodiment, which is not to be regarded as restricting the scope of the invention, with reference to FIGS. 1 and 2.

### ILLUSTRATIVE EMBODIMENTS

### Example 1

Layers of a fluorinated polymer were produced as shown in FIG. 1 by successive spin coating. To this end, a substrate coated over the entire area with ITO, prefabricated by Technoprint, was purchased. The ITO-coated substrates were cleaned in a clean room with deionised water and a detergent (Deconex 15 PF) and then activated by UV/ozone plasma treatment. A PEDOT layer (PEDOT is a polythiophene derivative (Baytron (now “Clevios”) P VAI 4083 sp.) from H. C. Starck, Goslar) with a thickness of 80 nm was then applied by spin coating in the clean room and dried by heating at 180° C. for 10 minutes in order to remove residual water. 20 nm of polymer IL1 were then applied by spin coating in a glove box under an argon atmosphere.

This polymer is a partially fluorinated copolymer. The polymer was prepared by Suzuki polymerisation, as described in WO 03/048225 A2, using the monomers shown below (percentage data=mol %). Owing to its high triphenylamine content, this polymer is suitable as interlayer in solution-processed OLEDs, i.e. it serves as interlayer between the buffer PEDOT/PSSH and polymers P1 or P2 deposited in a subsequent step and ensures efficient hole injection from PEDOT into this (or another) further polymer layer.

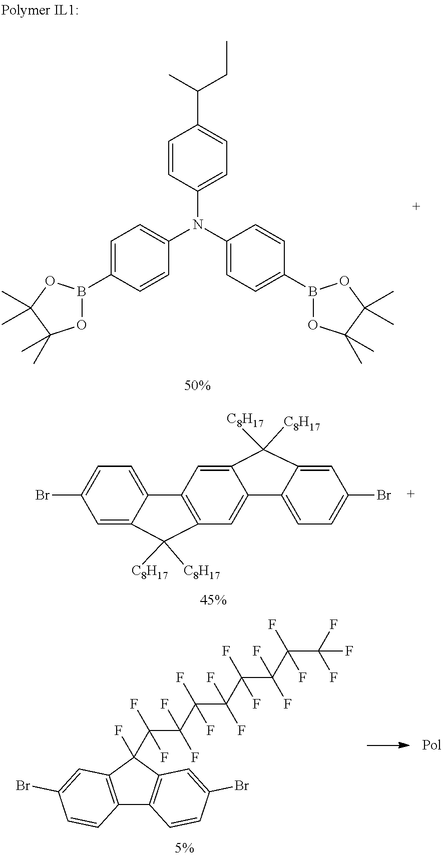

The requisite spin rate for a layer thickness of 20 nm was determined by spin coating of the polymers onto glass substrates from a solution having a concentration of 5 mg/ml. To this end, the film was applied by spin coating in a glove box under device production conditions and dried by heating at 180° C. for 1 hour. The layer thickness measurement was carried out using a profilometer (Dektak 3ST surface profiler from Veeco Instruments), which measures the layer thickness with the aid of a needle which moves over a cut made in the film using a scalpel and measures the depth thereof via a force measurement.

The spin rate for polymer IL1 was:

IL1 (5 mg/ml in toluene): 2400 rpm for 20 nm on glass.

### Comparative Example 2

Layers were produced analogously to Example 1 by successive spin coating.

However, the corresponding unfluorinated copolymer IL2 was employed instead of the partially fluorinated polymer. This polymer was also prepared by Suzuki polymerisation, as described in WO 03/048225 A2, using the monomers shown below (percentage data=mol %). Owing to its high triphenylamine content, this polymer is also suitable as interlayer in solution-processed OLEDs, i.e. it serves as interlayer between the buffer PEDOT/PSSH and polymers P1 or P2 deposited in a subsequent step and ensures efficient hole injection from PEDOT into this (or another) further polymer layer.

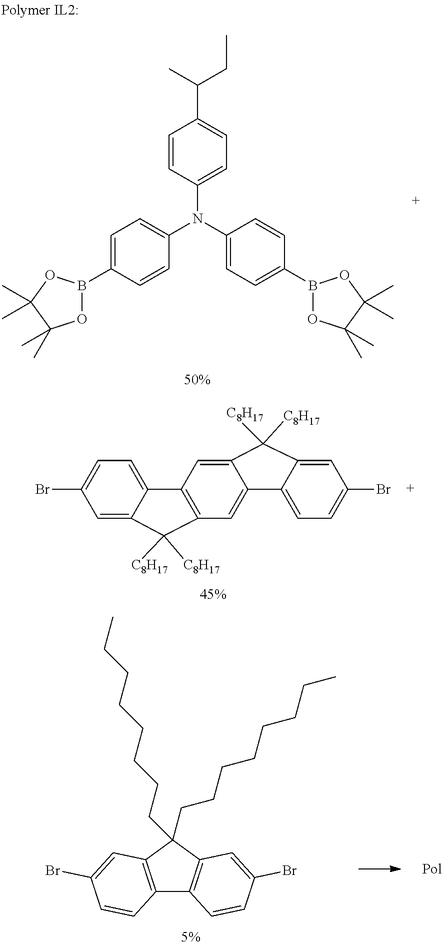

The requisite spin rate for a layer thickness of 20 nm was determined analogously to Example 1. For polymer IL2, it was:

IL2 (5 mg/ml in toluene): 1810 rpm for 20 nm on glass.

Comparison of the spin rates for polymers IL1 and IL2 shows that the cohesive forces of solution IL1 were significantly greater than those of IL2 since the spin rate required for IL1 was significantly higher than for IL2.

### Example 3

Since the interlayer polymers employed in Examples 1 and 2 were polymers which contained no chemically crosslinkable groups (for example oxetane groups), the further build-up of a layer structure as shown in FIG. 2 should result in the interlayer applied first being at least partially washed off again. In order to check this for polymers IL1 and IL2, layers were produced on PEDOT with the spin rate as determined for glass and again dried by heating at 180° C. for 1 hour. Both polymers gave (owing to the different spin rates) the same layer thicknesses of 15 nm.

IL1 (5 mg/ml in toluene), 2400 rpm on PEDOT: 15 nm
IL2 (5 mg/ml in toluene), 1810 rpm on PEDOT: 15 nm

The layers were subsequently overcoated with toluene (pure solvent) by spin coating at 1000 rpm. Whereas the partially fluorinated polymer IL1 behaved as if physically crosslinked owing to the strong fluorine-fluorine interaction and therefore could not be dissolved again, more than 50% of IL2 were washed off.

15 nm of IL1 on PEDOT, overcoated with toluene by spin coating at 1000 rpm: 15 nm
15 nm of IL2 on PEDOT, overcoated with toluene by spin coating at 1000 rpm: 6 nm

This clearly shows that a film of a partially fluorinated polymer can no longer be partially dissolved or washed off in a further coating step owing to the cohesive interaction between the chains, whereas a film of the same unfluorinated polymer can very easily be partially dissolved or washed off.

### Example 4

The aim now was to test whether the approach to physical crosslinking via a fluorine-fluorine interaction is also suitable for depositing a plurality of layers one on top of the other from the same solvent (toluene).

To this end, 80 nm of each of polymers P1 and P2 were coated on top of the prepared films of IL1 and IL2 (from toluene, 5 mg/ml, above-mentioned spin rates, 1 hour at 180° C.), as shown in FIG. 2. The polymers were prepared by Suzuki polymerisation, as described in WO 03/048225 A2, using the monomers shown below (percentage data=mol %).

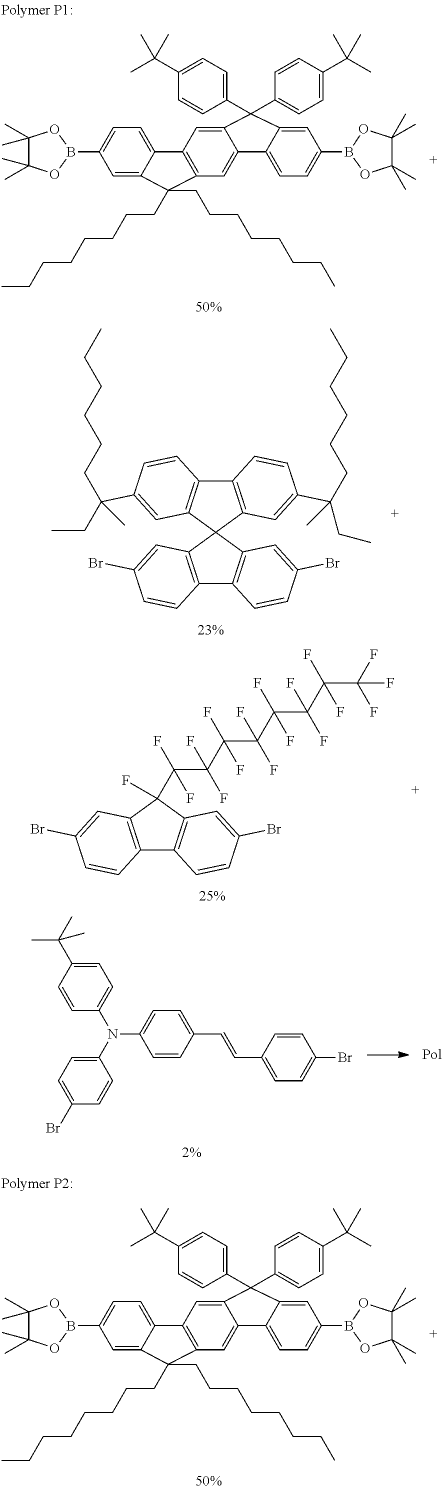

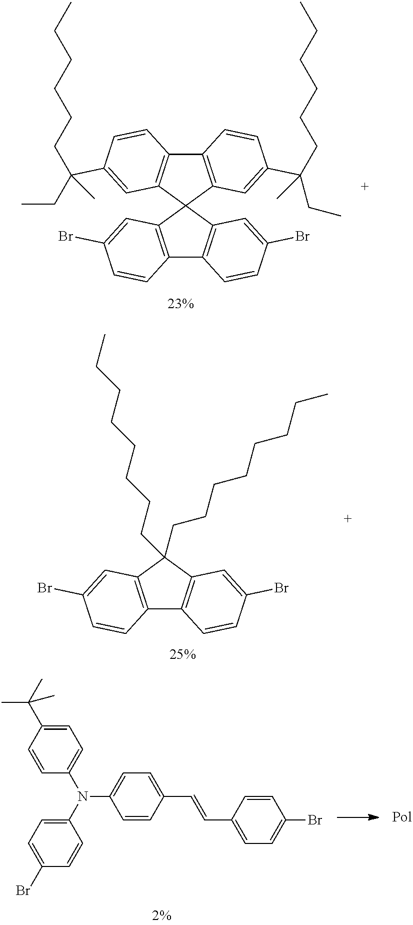

Owing to the conjugated poly-para-phenylene backbone and the low percentage of triarylamine emitter, these polymers P1 and P2 are blue-emitting polymers. They were likewise prepared by Suzuki polymerisation, as described in WO 03/048225 A2. Solutions in toluene in a concentration of 8 mg/ml were prepared, and the spin rates on glass for a polymer layer thickness of 80 nm were determined. The solutions were then used to coat a layer on top of the prepared films of IL1 and IL2. After the coating, the films were dried by heating at 180° C. for 10 minutes.

The following total layer thicknesses were determined:

IL1 with P1: 95 nm layer thickness (15 nm of IL1 plus 80 nm of P1)
IL1 with P2: 95 nm layer thickness (15 nm of IL1 plus 80 nm of P2)
IL2 with P1: 86 nm layer thickness (6 nm of IL2 plus 80 nm of P1)
IL2 with P2: 86 nm layer thickness (6 nm of IL2 plus 80 nm of P2)

In the first two cases, in which polymer P1 or P2 was applied to interlayer IL1 (partially fluorinated copolymer), total layer thicknesses were obtained which correspond to the addition of the interlayer (15 nm) plus the layer thickness of the polymer layer of P1 or P2 (80 nm).

In the latter two cases, in which polymer P1 or P2 was applied to interlayer IL2 (unfluorinated copolymer), total layer thicknesses were obtained which were less than the sum of the thickness of the interlayer (15 nm) and the thickness of the polymer layer of P1 or P2 (80 nm), i.e. at least part of the interlayer has been partially dissolved and washed off during application of the polymer layer, as was also the case on overcoating by spin coating with the pure solvent.

### Example 5

The layers obtained in Example 4 were again overcoated by spin coating with pure toluene at 1000 rpm as in Example 3 in order again to test the physical crosslinking of the partially fluorinated film.

The total layer thicknesses before treatment with toluene and after treatment with toluene were determined. The results are shown in the following table:

| Example | Layer sequence | Before | After |
|---|---|---|---|
| 5a | IL1 with P1 | 95 nm (15 + 80 nm) | 76 nm (15 + 61 nm) |
| 5b | IL1 with P2 | 95 nm (15 + 80 nm) | 16 nm (15 + 01 nm) |
| 5c | IL2 with P1 | 86 nm (6 + 80 nm) | 67 nm (06 + 61 nm) |
| 5d | IL2 with P2 | 86 nm (6 + 80 nm) | 03 nm (03 + 00 nm) |

As the table shows, only a small part of the polymer layer was washed off in Examples 5a and 5c owing to the fluorine-fluorine interaction which results in “physical crosslinking”. This is underlined once more by the fact that the same amount of fluorinated polymer P1 is removed in each case irrespective of the underlying interlayer (19 nm in each case).

By contrast, virtually the entire or the entire polymer layer was washed off in Examples 5b and 5d owing to the lack of fluorine-fluorine interaction. In Example 5d, in addition, part of the unfluorinated interlayer was additionally washed off.

### Example 6

As shown in Examples 1 and 2, the different spin rates (for the same concentration) indicated different cohesion of the chains and consequently different viscosity of the solutions. Conversely, the two solutions were then coated under identical spin conditions.

The following layer thicknesses were obtained:

IL1 (5 mg/ml in toluene): 2400 rpm=>20 nm on glass
IL2 (5 mg/ml in toluene): 2400 rpm=>15 nm on glass

As the results show, significantly more material was spun off in the case of the unfluorinated polymer IL2 than in the case of the partially fluorinated polymer IL1, where the fluorine-fluorine interaction has prevented this.

1. Opto-electronic device comprising at least one layer comprising a polymer containing fluorine-containing groups, where a cohesive fluorine-fluorine interaction exists at least between some of the fluorine-containing groups of the layer.

2. Opto-electronic device according to claim 1, characterised in that the layer comprises a polymer having a charge-injection and/or charge-transport function.

3. Opto-electronic device according to claim, characterised in that the layer comprises a polymer having an emitter function.

4. Opto-electronic device according to claim 1, characterised in that the polymer is a blend of two or more polymers.

5. Opto-electronic device according to claim 1, comprising at least one further layer.

6. Opto-electronic device according to claim 5, characterised in that the further layer comprises a polymer having a hole-injection function, hole-transport function, hole-blocking function, emitter function, electron-injection function, electron-blocking function and/or electron-transport function.

7. Opto-electronic device according to claim 5, characterised in that the further layer comprises a polymer containing fluorine-containing groups.

8. Opto-electronic device according to claim 6, characterised in that the polymer has an emitter function.

9. Opto-electronic device according to claim 8, characterised in that the polymer having an emitter function emits light of various wavelengths.

10. Opto-electronic device according to claim 6, characterised in that the device comprises a plurality of layers of polymers having an emitter function.

11. Opto-electronic device according to claim 10, characterised in that the plurality of layers of polymers having an emitter function each emit light of different wavelength.

12. Opto-electronic device according to claim 9, characterised in that the various light wavelengths add up to the colour white.

13. Opto-electronic device according to claim 9, characterised in that the device comprises three layers having the primary colours red, green and blue.

14. Opto-electronic device according to claim 9, characterised in that at least one of the layers comprises singlet emitters, but at least one of the other layers comprises triplet emitters.

15. Opto-electronic device according to claim 2, characterised in that the device comprises a plurality of layers of polymers having a hole-transport function (so-called hole conductors), where the hole conductors have energetically different highest occupied molecular orbitals (HOMO).

16. Opto-electronic device according to claim 15, characterised in that the polymer layer having a hole-transport function which was applied last has an energetically high lowest unoccupied molecular orbital (LUMO).

17. Opto-electronic device according to claim 16, characterised in that the polymer layer having a hole-transport function which was applied last is an electron-blocking layer.

18. Opto-electronic device according to claim 1, characterised in that the device comprises a plurality of layers of polymers having an electron-transport function (so-called electron conductors), where the electron conductors have energetically different lowest unoccupied molecular orbitals (LUMO).

19. Opto-electronic device according to claim 18, characterised in that the polymer layer having an electron-transport function which was applied first has an energetically low highest occupied molecular orbital (HOMO).

20. Opto-electronic device according to claim 19, characterised in that the polymer layer having an electron-transport function which was applied first is a hole-blocking layer.

21. Opto-electronic device according to claim 1, characterised in that the device comprises a layer comprising small molecules or oligomers.

22. Opto-electronic device according to claim 1, characterised in that an adhesive fluorine-fluorine interaction exists between some of the fluorine-containing groups of the first layer and the at least one further layer.

23. Opto-electronic device according to claim 1, characterised in that the device comprises a cathode and an anode.

24. Opto-electronic device according to claim 23, characterised in that the anode is an indium tin oxide (ITO) layer or an indium zinc oxide (IZO) layer.

25. Opto-electronic device according to claim 23, characterised in that the cathode and/or anode is (are) a conductive polymer.

26. Opto-electronic device according to claim 23, characterised in that the anode consists of an indium tin oxide (ITO) layer or an indium zinc oxide (IZO) layer and a layer of a conductive polymer.

27. Use of an opto-electronic device according to claim 1 as organic or polymeric light-emitting diode, as organic solar cell, as organic field-effect transistor, as organic integrated circuit, as organic field-quench element, as organic optical amplifier, as organic laser diode, as organic photoreceptor or as organic photodiode.

28. Use according to claim 27 as OLED in a display, in a coloured, multicoloured or full-colour display, as lighting element or as backlight in a liquid-crystal display (LCD).

29. Use according to claim 28, characterised in that the OLED is a white light-emitting OLED.

30. Process for the production of an opto-electronic device according to claim 1, comprising the production of a layer of a polymer containing fluorine-containing groups.

31. Formulation comprising one or more fluorine-containing polymers and/or fluorine-containing blends and/or fluorinated small molecules in one or more solvents.
